(19) United States
(12) Patent Application Publication
(10) Pub. No.: US 2020/0241058 A1
(43) Pub. Date: Jul. 30, 2020

(54) METHOD AND DEVICE FOR OBTAINING AN INITIAL RESISTANCE VALUE OF A HEATING ELEMENT

(71) Applicant: Changzhou Patent Electronic Technology Co., LTD., Changzhou City (CN)

(72) Inventor: WEIHUA QIU, Changzhou City (CN)

(21) Appl. No.: 16/775,252

(22) Filed: Jan. 28, 2020

(30) Foreign Application Priority Data
Jan. 29, 2019 (CN) 201910085814.2

(51) Int. Cl. G01R 27/02; G01K 7/22; H05B 1/02

(52) U.S. Cl. CPC G01R 27/02; H05B 1/0297; G01K 7/22

(57) ABSTRACT

The present invention discloses a method and a device for obtaining an initial resistance value of a heating element. The method comprises steps: when ambient temperature is a preset test temperature, detecting a resistance value of a heating element to obtain the resistance value of the heating element at the preset test temperature; determining the resistance value of the heating element at the preset test temperature as the initial resistance value of the heating element. It solves the problem that the initial resistance value of the heating element in the related technology is measured manually on the assembly line and measurement efficiency is low. The measurement efficiency of the initial resistance value of the heating element of the invention is improved.

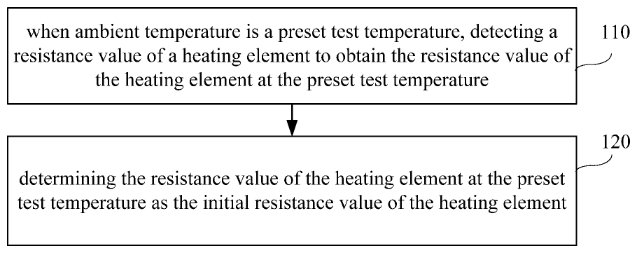

### TECHNICAL FIELD

The present invention relates to the field of simulation smoking technologies, in particular to a method and a device for obtaining an initial resistance value of a heating element.

### BACKGROUND

At present, electronic cigarette, as a substitute of tobacco products, is more and more popular in the market because of its portability and producing large amount of smoke.

When the electronic cigarette with temperature control function is assembled on production line, worker manually measures resistance value of the heating element of the electronic cigarette at room temperature (for example, 25° C.), which is stored in memory as an initial resistance value of the heating element. At present, the initial resistance value of the heating element is measured manually on the production line, which consumes a lot of human resources, and the measurement efficiency is low.

### SUMMARY

In order to overcome the above technical defects, for example, the initial resistance value of the heating element in the related technology is measured manually on the production line, which consumes a lot of human resources, and the measurement efficiency is low. The present invention provides a method and a device for obtaining an initial resistance value of a heating element. The technical solution is as follows:

In a first aspect, a method for obtaining an initial resistance value of a heating element is provided. The method includes: when ambient temperature is a preset test temperature, detecting a resistance value of a heating element to obtain the resistance value of the heating element at the preset test temperature; determining the resistance value of the heating element at the preset test temperature as the initial resistance value of the heating element.

In one embodiment of the present invention, the step of detecting a resistance value of a heating element to obtain the resistance value of the heating element at the preset test temperature, further comprising: providing the heating element with a preset detection voltage; detecting current value of the heating element at the preset detection voltage; determining the resistance value of the heating element at the preset test temperature according to the current value and the preset detection voltage.

In one embodiment of the present invention, the step of detecting a resistance value of a heating element to obtain the resistance value of the heating element at the preset test temperature, further comprising: when a cigarette lighting signal is detected, controlling the heating element to work according to a preset heating rule, which includes a working voltage range of the heating element and/or a working output power range; before the resistance value of the heating element reaches a preset resistance value, voltage value and current value of the heating element are recorded for many times; when the resistance value of the heating element reaches the preset resistance value, obtaining a working duration time of the heating element according to the preset heating rule; determining the resistance value of the heating element at the preset test temperature according the voltage value, current value recorded for many times and working duration time.

In one embodiment of the present invention, the step of determining the resistance value of the heating element at the preset test temperature according the voltage value, current value recorded for many times and working duration time, further comprising: calculating the resistance value of the heating element at the preset test temperature according to a preset formula, which is:

$${R}_{0} = \frac{R}{α ( c {\sum }_{n = 1}^{m} I ( {t}_{n} ) * V ( {t}_{n} ) * Δ t + {d ( {\sum }_{n = 1}^{m} I ( {t}_{n} ) * V ( {t}_{n} ) * Δ t )}^{2} ) + 1} + D ,$$

wherein R0 is the resistance value of the heating element at the preset test temperature, R is the preset resistance value, α, c, d and D are constants, I(tₙ) is the current value recorded for the nth time during the heating element works according to the preset heating rule, V(tₙ) is the voltage value recorded for the nth time during the heating element works according to the preset heating rule, At is the duration time, and m is total number of recorded times of the current value during the heating element works according to the preset heating rule.

In one embodiment of the present invention, the step of when ambient temperature is a preset test temperature, detecting an resistance value of a heating element to obtain the resistance value of the heating element at the preset test temperature, further comprising: obtaining a resistance value of the thermistor which indicates the ambient temperature; when the resistance value of the thermistor is within a preset range, the ambient temperature is determined as the preset test temperature, detecting an resistance value of a heating element to obtain the resistance value of the heating element at the preset test temperature.

In one embodiment of the present invention, before the step of when ambient temperature is a preset test temperature, detecting an resistance value of a heating element to obtain the resistance value of the heating element at the preset test temperature, further comprising: when a cigarette lighting signal is detected, controlling the heating element to heat; when the cigarette lighting signal is detected to be interrupted, determining required cooling time for the heating element to cool down to the preset test temperature; when the cigarette lighting signal is interrupted continuously to reach the cooling time, performing the step of when ambient temperature is a preset test temperature, detecting an resistance value of a heating element to obtain the resistance value of the heating element at the preset test temperature.

In one embodiment of the present invention, the step of determining required cooling time for the heating element to cool down to the preset test temperature, further comprising: obtaining temperature of the heating element when the cigarette lighting signal is interrupted to get an initial cooling temperature of the heating element; obtaining a first stop heating time corresponding to the initial cooling temperature in a preset corresponding relationship; obtaining a second stop heating time corresponding to the ambient temperature in the preset corresponding relationship; calculating difference between the second stop heating time and the first stop heating time to obtain the cooling time.

In one embodiment of the present invention, before the step of detecting an resistance value of a heating element to obtain the resistance value of the heating element at the preset test temperature, further comprising: when the cigarette lighting signal is detected, controlling the heating element to heat; when a cigarette lighting signal is interrupted continuously for a preset cooling time, performing the step of when ambient temperature is a preset test temperature, detecting an resistance value of a heating element to obtain the resistance value of the heating element at the preset test temperature, wherein the preset cooling time equal to required cooling time when cooling the heating element from its maximum temperature to the preset test temperature, and maximum temperature of the heating element is maximum temperature value that the heating element can reach for continuous heating.

In one embodiment of the present invention, the step of when ambient temperature is a preset test temperature, detecting an resistance value of a heating element to obtain the resistance value of the heating element at the preset test temperature, further comprising: after the electronic cigarette is turned on, check whether the initial resistance value of the heating element is stored in the electronic cigarette; if the initial resistance value of the heating element is not stored in the electronic cigarette, performing the step of when ambient temperature is a preset test temperature, detecting an resistance value of a heating element to obtain the resistance value of the heating element at the preset test temperature.

In one embodiment of the present invention, the step of when ambient temperature is a preset test temperature, detecting an resistance value of a heating element to obtain the resistance value of the heating element at the preset test temperature, further comprising: obtaining storage time of the initial resistance value of the heating element stored in the electronic cigarette; when time interval between current time and the storage time reaches a preset update cycle, performing the step of when ambient temperature is a preset test temperature, detecting an resistance value of a heating element to obtain the resistance value of the heating element at the preset test temperature.

In a second aspect, a computer readable storage medium having stored therein one or more instructions, wherein the one or more instructions are executed by a processor within an electronic cigarette to implement the method for obtaining an initial resistance value of a heating element of the first aspect of the present invention.

In a third aspect, a device for obtaining an initial resistance value of a heating element, comprising: a memory and a processor; wherein the memory stores therein at least one program instruction; the processor, by executing the at least one program instruction, implements the method for obtaining an initial resistance value of a heating element of the first aspect of the present invention.

The beneficial effects brought by the technical solutions provided by the embodiments of the present invention are:

The invention detects the resistance value of the heating element to obtain the resistance value of the heating element at the preset test temperature, and determines the resistance value of the heating element at the preset test temperature as the initial resistance value of the heating element; solves the problem that the initial resistance value of the heating element in the related technology is measured manually on the assembly line and measurement efficiency is low. The measurement efficiency of the initial resistance value of the heating element of the invention is improved.

### BRIEF DESCRIPTION OF THE DRAWINGS

In order to more clearly illustrate the technical solutions in the embodiments of the present invention, the drawings used in the description of the embodiments will be briefly described below. It is obvious that the drawings in the following description are only some embodiments of the present invention. For those of ordinary skill in the art, other drawings may also be obtained in light of these drawings without any creative efforts.

The FIGURE is a flow diagram of a method for obtaining an initial resistance value of a heating element according to an embodiment of the present invention.

Specific embodiments of the present disclosure have been shown by the above-mentioned drawings and will be described in more detail later. These drawings and textual descriptions are not intended to limit the scope of the present disclosure in any way, but to explain the concepts of the present disclosure to those skilled in the art by referring to specific embodiments.

### DETAILED DESCRIPTION OF PREFERRED EMBODIMENTS

In order to make the objects, the technical solution and the advantages of the present invention much clear, the embodiments of the present invention will be further described in detail below with reference to the accompanying drawings.

It should be noted that the following specific embodiments may be combined with each other, and the same or similar concepts or processes may not be repeated in some embodiments.

Referring to the FIGURE, it is a flow diagram of a method for obtaining an initial resistance value of a heating element according to an embodiment of the present invention. In this embodiment, the method is used in electronic cigarette for example. The method for obtaining the initial resistance value of the heating element can include:

Step 110, when ambient temperature is a preset test temperature, detecting a resistance value of a heating element to obtain the resistance value of the heating element at the preset test temperature.

Among them, the preset test temperature is set by system developer. The system developer can set a single temperature value as the preset test temperature to be stored in the electronic cigarette, or set a value range of the preset test temperature. For example, the system developer can set the preset test temperature to be 25° C.

This step determines whether ambient temperature is a preset test temperature, which can be achieved in the following ways:

First way is as follows: the electronic cigarette is provided with a temperature detection device (for example, a temperature sensor); obtaining the ambient temperature detected by the temperature detection device; and determining whether the ambient temperature detected by the temperature detection device is a preset test temperature.

Second way is as follows: a thermistor is arranged on the electronic cigarette, and the resistance value of the thermistor is used to indicate the ambient temperature. In practice, the thermistor can be set far away from heat source in the electronic cigarette to avoid the influence of the heat source on the thermistor, for example, it is set on the printed circuit board (PCB) in the electronic cigarette. The heating source can include the heating element in the atomizer, the processor of the electronic cigarette, the battery component in the electronic cigarette, or other devices that are easy to heat.

In addition, the thermistor involved in this application may be an NTC (Negative Temperature Coefficient) thermistor.

In detail, the second way can include: obtaining a resistance value of the thermistor, when the resistance value of the thermistor is within a preset range, the ambient temperature is determined as the preset test temperature. The preset range is set by the system developer. The value range set by the system developer can include multiple values or only a single value. For example, the preset range only includes the resistance value of the thermistor at the preset test temperature. In practice, the system developer can set the preset range according to the resistance value of the thermistor at the preset test temperature.

Third way is as follows: when a cigarette lighting signal is detected, controlling the heating element to heat; when the cigarette lighting signal is detected to be interrupted, determining required cooling time for the heating element to cool down to the preset test temperature; when the cigarette lighting signal is interrupted continuously to reach the cooling time, determining the ambient temperature to be the preset test temperature.

In the application, if detecting the cigarette lighting signal when the initial resistance value of the heating element needs to be determined, the heating element can be controlled to work according to a preset mode. The preset mode is not specifically limited in the application. For example, the electronic cigarette can provide a constant voltage to the heating element or randomly change the voltage provided to the heating element. That is to say, when the initial resistance value of the heating element of the electronic cigarette needs to be determined, the electronic cigarette user can use the electronic cigarette for suction for a period of time.

Optionally, determining cooling time required for the heating element to cool down to the preset test temperature, can include: obtaining temperature of the heating element when the cigarette lighting signal is interrupted to get an initial cooling temperature of the heating element; obtaining a first stop heating time corresponding to the initial cooling temperature in a preset corresponding relationship; obtaining a second stop heating time corresponding to the ambient temperature in the preset corresponding relationship. Calculating difference between the second stop heating time and the first stop heating time to obtain the cooling time.

The step of obtaining temperature of the heating element when the cigarette lighting signal is interrupted to get an initial cooling temperature of the heating element, can include: the heating element is provided with a thermistor whose resistance value is used to indicate the temperature of the heating element; when the cigarette lighting signal is interrupted, obtaining the resistance value of the thermistor set on the heating element; determining the temperature of the heating element according to the resistance value of the thermistor. Specifically, corresponding relationship between the resistance value of the thermistor and the temperature can be stored in the electronic cigarette, and the temperature of the heating element can be got by obtaining the temperature of the thermistor corresponding to the resistance value of the thermistor from the corresponding relationship.

Optionally, the preset corresponding relationship involved in this application is: T=k*e^{g(t-m)}+n, wherein, T is the temperature of the heating element, t is stop heating time, k, g, m are fixed values, e is a natural constant. For example, the value of k can be 195.5, the value of b can be 0.02, the value of m can be 21.3809, and the value of n can be 30.

Fourth way is as follows: when the cigarette lighting signal is detected, controlling the heating element to heat; when a cigarette lighting signal is interrupted continuously for a preset cooling time, current ambient temperature is determined as the preset test temperature.

Among them, the preset cooling time is set by the system developer. The system developer can set the preset cooling time equal to required cooling time when cooling the heating element from its maximum temperature to the preset test temperature. Maximum temperature of the heating element mentioned here is maximum temperature value that the heating element can reach for continuous heating.

Optionally, the step of detecting a resistance value of a heating element to obtain the resistance value of the heating element at the preset test temperature, can include two ways:

First way is as follows: providing the heating element with a preset detection voltage; detecting current value of the heating element at the preset detection voltage; and determining the resistance value of the heating element at the preset test temperature according to the current value and the preset detection voltage. Wherein, the resistance value of the heating element at the preset test temperature can be obtained by calculating ratio between the preset test voltage and the current value; or the electronic cigarette can store preset test voltage and corresponding relationship between the resistance value of the heating element and the current value of the heating element; obtaining the resistance value corresponding to the detected current value of the heating element from the corresponding relationship to get the resistance value of the heating element in the preset test temperature. Among them, the corresponding relationship can be displayed and stored in the electronic cigarette by tables, curves, etc.

Second way is as follows: when a cigarette lighting signal is detected, controlling the heating element to work according to a preset heating rule, which includes a working voltage range of the heating element and/or a working output power range; before the resistance value of the heating element reaches a preset resistance value, voltage value and current value of the heating element are recorded for many times; when the resistance value of the heating element reaches the preset resistance value, obtaining a working duration time of the heating element according to the preset heating rule, determining the resistance value of the heating element at the preset test temperature according the voltage value, current value recorded for many times and working duration time.

Among them, the working voltage range and/or the working output power range of the heating element can be set by the system developer. In the actual implementation, when the system developer sets the heating rule, they can directly set a preset working voltage or a preset output power. When the electronic cigarette detects the cigarette lighting signal, it can provide the preset working voltage to the heating element or control the heating element to work according to the preset output power.

It should be noted that the maximum value of the working voltage range of the heating element set by the system developer is lower than a preset proportion of the maximum working voltage of the heating element, which can be one quarter, one fifth, etc. The embodiment does not specifically limit the preset proportion. The maximum value of the working output power range of the heating element set by the system developer is lower than a preset proportion of the maximum output power of the heating element, which can be one fourth, one fifth, etc.

Optionally, calculating the resistance value of the heating element at the preset test temperature according to a preset formula, which is:

$${R}_{0} = \frac{R}{α ( c {\sum }_{n = 1}^{m} I ( {t}_{n} ) * V ( {t}_{n} ) * Δ t + {d ( {\sum }_{n = 1}^{m} I ( {t}_{n} ) * V ( {t}_{n} ) * Δ t )}^{2} ) + 1} + D ,$$

wherein R0 is the resistance value of the heating element at the preset test temperature, R is the preset resistance value, α, c, d and D are constants, I(tₙ) is the current value recorded for the nth time during the heating element works according to the preset heating rule, V(tₙ) is the voltage value recorded for the nth time during the heating element works according to the preset heating rule, At is the duration time, and m is total number of recorded times of the current value during the heating element works according to the preset heating rule.

It should be noted that the values of c and d in the formula depend on volume and shape of the heating element, so c and d are usually set by the system developer according to the volume and shape of the heating element; the value of a usually depends on material of the heating element, so the value of a is usually set by the system developer according to material of the heating element.

Optionally, in the process of controlling the heating element to work according to the preset heating rule, the voltage value and current value of the heating element are recorded once for a preset time interval. Among them, the preset time interval is set by the system developer, for example, the system developer can set the preset time interval to 0.2 second, 0.3 second, etc.

Third way is as follows: when the cigarette lighting signal is detected, controlling the heating element to work according to the preset heating rule; before the resistance value of the heating element reaches the preset resistance value, the output power of the heating element is recorded for many times; when the resistance value of the heating element reaches the preset resistance value, obtaining the working duration time of the heating element according to the preset heating rule; determining resistance value of the heating element at preset test temperature according to the output power and working duration time recorded for many times.

Among them, calculating the resistance value of the heating element under the preset test temperature according to the following formula:

$${R}_{0} = \frac{R}{α ( c {\sum }_{n = 1}^{m} P ( {t}_{n} ) * Δ t + {d ( {\sum }_{n = 1}^{m} P ( {t}_{n} ) * Δ t )}^{2} ) + 1} + D ,$$

wherein α, c, d, and D are constants, P(tₙ) is output power recorded for the nth time during the heating element works according to the preset heating rule, Δt is the duration time, and m is the total number of recorded times of the output power of the heating element during the heating element works according to the preset heating rule.

Optionally, in the process of controlling the heating element to work according to the preset heating rule, the output power of the heating element is recorded once for a preset time interval. Among them, the preset time interval is set by the system developer, for example, the system developer can set the preset time interval to 0.2 second, 0.3 second, etc.

Step 120, determining the resistance value of the heating element at the preset test temperature as the initial resistance value of the heating element.

When the initial resistance value of the heating element is determined and the electronic cigarette enters a temperature control mode, the temperature of the electronic cigarette can be controlled according to the initial resistance value.

The method provided by the embodiment of the invention detects the resistance value of the heating element to obtain the resistance value of the heating element at the preset test temperature, and determines the resistance value of the heating element at the preset test temperature as the initial resistance value of the heating element; solves the problem that the initial resistance value of the heating element in the related technology is measured manually on the assembly line and measurement efficiency is low. The measurement efficiency of the initial resistance value of the heating element of the invention is improved.

Optionally, after the electronic cigarette is turned on, or when the electronic cigarette enters a temperature control mode, check whether the initial resistance value of the heating element is stored in the electronic cigarette; if the initial resistance value of the heating element is not stored in the electronic cigarette, determining whether the ambient temperature is the preset test temperature; if the ambient temperature is the preset test temperature, performing step 110.

Because the resistance value of the heating element changes after long time working, it is easy to affect the temperature control effect of the electronic cigarette. In order to ensure the temperature control effect of the electronic cigarette, the electronic cigarette also updates the initial resistance value of the heating element. It can be realized in the following two ways:

First way is as follows, after the electronic cigarette is turned on, or when the electronic cigarette enters the temperature control mode, obtaining storage time of the initial resistance value of the heating element stored in the electronic cigarette; when time interval between current time and the storage time reaches a preset update cycle, determining whether the ambient temperature is the preset test temperature; when the ambient temperature is the preset test temperature, performing step 110. Among them, the preset update cycle can be set by the system developer, for example, the system developer can set the preset update cycle to one month.

Second way is as follows, after the electronic cigarette is turned on, or when the electronic cigarette enters the temperature control mode, obtaining accumulated heating time of the heating element after obtaining the storage time of the initial resistance value of the stored heating element in the electronic cigarette; when the accumulated heating time reaches preset update time, determining whether the ambient temperature is the preset test temperature; when the ambient temperature is the preset test temperature, performing step 110. Among them, the preset update time can be set by the system developer, for example, the system developer can set the preset update time to 50 hours.

Optionally, in the process of controlling the heating element of electronic cigarette according to the preset heating rule, prompt information can be displayed, which is used to remind electronic cigarette user that resistance value of the heating element is detected. Among them, the prompt information can be displayed by indicator light, text, buzzer, etc., which is not specifically limited in this embodiment.

Optionally, in the process of controlling the heating element to work in a preset way according to the cigarette lighting signal, the electronic cigarette can display prompt information, which is used to remind electronic cigarette user that resistance value of the heating element is detected. Among them, the prompt information can be displayed by indicator light, text, buzzer, etc., which is not specifically limited in this embodiment.

Optionally, the electronic cigarette controls the heating element to heat continuously according to the preset heating rule until the resistance value of the heating element reaches the preset resistance value, then controls the heating element to stop heating, and controls the initial resistance value of the heating element of the atomizer.

One embodiment of the invention also provides a computer readable storage medium, in which one or more instructions are stored. When the one or more instructions are executed by a processor in the electronic cigarette, a method for obtaining the initial resistance value of the heating element in any embodiment is implemented.

An embodiment of the invention also provides a device for obtaining the initial resistance value of the heating element, which includes a memory and a processor; at least one program instruction is stored in the memory; the processor implements the method for obtaining the initial resistance value of the heating element in any embodiment by loading and executing the at least one program instruction.

A person skilled in the art may understand that implementing all or part of the steps in the above embodiments may be completed by hardware, or may be executed by a computer program to instruct related hardware, and the computer program may be stored in a computer readable storage medium. The storage medium mentioned may be a read only memory, a magnetic disk, an optical disk, and the like.

The above are only the preferred embodiments of the present invention, and are not intended to limit the present invention. Any modifications, equivalents, improvements, etc., which are within the scope of the present invention, should be included in the protection scope of the present invention.

What is claimed is:

1. A method for obtaining an initial resistance value of a heating element, comprising:
when ambient temperature is a preset test temperature, detecting a resistance value of a heating element to obtain the resistance value of the heating element at the preset test temperature;
determining the resistance value of the heating element at the preset test temperature as the initial resistance value of the heating element.

2. The method according to claim 1, wherein the step of detecting a resistance value of a heating element to obtain the resistance value of the heating element at the preset test temperature, further comprising:
providing the heating element with a preset detection voltage;
detecting current value of the heating element at the preset detection voltage;
determining the resistance value of the heating element at the preset test temperature according to the current value and the preset detection voltage.

3. The method according to claim 1, wherein the step of detecting a resistance value of a heating element to obtain the resistance value of the heating element at the preset test temperature, further comprising:
when a cigarette lighting signal is detected, controlling the heating element to work according to a preset heating rule, which includes a working voltage range of the heating element and/or a working output power range;
before the resistance value of the heating element reaches a preset resistance value, voltage value and current value of the heating element are recorded for many times;
when the resistance value of the heating element reaches the preset resistance value, obtaining a working duration time of the heating element according to the preset heating rule;
determining the resistance value of the heating element at the preset test temperature according the voltage value, current value recorded for many times and working duration time.

4. The method according to claim 3, wherein the step of determining the resistance value of the heating element at the preset test temperature according the voltage value, current value recorded for many times and working duration time, further comprising:
calculating the resistance value of the heating element at the preset test temperature according to a preset formula, which is:
$${R}_{0} = \frac{R}{α ( c {\sum }_{n = 1}^{m} I ( {t}_{n} ) * V ( {t}_{n} ) * Δ t + {d ( {\sum }_{n = 1}^{m} I ( {t}_{n} ) * V ( {t}_{n} ) * Δ t )}^{2} ) + 1} + D ;$$
wherein R0 is the resistance value of the heating element at the preset test temperature, R is the preset resistance value, α, c, d and D are constants, I(tₙ) is the current value recorded for the nth time during the heating element works according to the preset heating rule, V(tₙ) is the voltage value recorded for the nth time during the heating element works according to the preset heating rule, Δt is the duration time, and m is total number of recorded times of the current value during the heating element works according to the preset heating rule.

5. The method according to claim 1, wherein the step of when ambient temperature is a preset test temperature, detecting a resistance value of a heating element to obtain the resistance value of the heating element at the preset test temperature, further comprising:
obtaining a resistance value of the thermistor which indicates the ambient temperature;
when the resistance value of the thermistor is within a preset range, the ambient temperature is determined as the preset test temperature, detecting a resistance value of a heating element to obtain the resistance value of the heating element at the preset test temperature.

6. The method according to claim 1, wherein before the step of when ambient temperature is a preset test temperature, detecting a resistance value of a heating element to obtain the resistance value of the heating element at the preset test temperature, further comprising:
when a cigarette lighting signal is detected, controlling the heating element to heat;
when the cigarette lighting signal is detected to be interrupted, determining required cooling time for the heating element to cool down to the preset test temperature;
when the cigarette lighting signal is interrupted continuously to reach the cooling time, performing the step of when ambient temperature is a preset test temperature, detecting a resistance value of a heating element to obtain the resistance value of the heating element at the preset test temperature.

7. The method according to claim 6, wherein the step of determining required cooling time for the heating element to cool down to the preset test temperature, further comprising:
obtaining temperature of the heating element when the cigarette lighting signal is interrupted to get an initial cooling temperature of the heating element;
obtaining a first stop heating time corresponding to the initial cooling temperature in a preset corresponding relationship;
obtaining a second stop heating time corresponding to the ambient temperature in the preset corresponding relationship;
calculating difference between the second stop heating time and the first stop heating time to obtain the cooling time.

8. The method according to claim 1, wherein before the step of detecting a resistance value of a heating element to obtain the resistance value of the heating element at the preset test temperature, further comprising:
when the cigarette lighting signal is detected, controlling the heating element to heat;
when a cigarette lighting signal is interrupted continuously for a preset cooling time, performing the step of when ambient temperature is a preset test temperature, detecting an resistance value of a heating element to obtain the resistance value of the heating element at the preset test temperature, wherein the preset cooling time equal to required cooling time when cooling the heating element from its maximum temperature to the preset test temperature, and maximum temperature of the heating element is maximum temperature value that the heating element can reach for continuous heating.

9. The method according to claim 1, wherein the step of when ambient temperature is a preset test temperature, detecting a resistance value of a heating element to obtain the resistance value of the heating element at the preset test temperature, further comprising:
after the electronic cigarette is turned on, check whether the initial resistance value of the heating element is stored in the electronic cigarette;
if the initial resistance value of the heating element is not stored in the electronic cigarette, performing the step of when ambient temperature is a preset test temperature, detecting a resistance value of a heating element to obtain the resistance value of the heating element at the preset test temperature.

10. The method according to claim 1, wherein the step of when ambient temperature is a preset test temperature, detecting a resistance value of a heating element to obtain the resistance value of the heating element at the preset test temperature, further comprising:
obtaining storage time of the initial resistance value of the heating element stored in the electronic cigarette;
when time interval between current time and the storage time reaches a preset update cycle, performing the step of when ambient temperature is a preset test temperature, detecting a resistance value of a heating element to obtain the resistance value of the heating element at the preset test temperature.

11. A computer readable storage medium having stored therein one or more instructions, wherein the one or more instructions are executed by a processor within an electronic cigarette to implement the method for obtaining an initial resistance value of a heating element according to claim 1.

12. The computer readable storage medium according to claim 11, wherein the step of detecting a resistance value of a heating element to obtain the resistance value of the heating element at the preset test temperature, further comprising:
providing the heating element with a preset detection voltage;
detecting current value of the heating element at the preset detection voltage;
determining the resistance value of the heating element at the preset test temperature according to the current value and the preset detection voltage.

13. The computer readable storage medium according to claim 11, wherein the step of detecting a resistance value of a heating element to obtain the resistance value of the heating element at the preset test temperature, further comprising:
when a cigarette lighting signal is detected, controlling the heating element to work according to a preset heating rule, which includes a working voltage range of the heating element and/or a working output power range;
before the resistance value of the heating element reaches a preset resistance value, voltage value and current value of the heating element are recorded for many times;
when the resistance value of the heating element reaches the preset resistance value, obtaining a working duration time of the heating element according to the preset heating rule;
determining the resistance value of the heating element at the preset test temperature according the voltage value, current value recorded for many times and working duration time.

14. The computer readable storage medium according to claim 11, wherein the step of determining the resistance value of the heating element at the preset test temperature according the voltage value, current value recorded for many times and working duration time, further comprising:
calculating the resistance value of the heating element at the preset test temperature according to a preset formula, which is:
$${R}_{0} = \frac{R}{α ( c {\sum }_{n = 1}^{m} I ( {t}_{n} ) * V ( {t}_{n} ) * Δ t + {d ( {\sum }_{n = 1}^{m} I ( {t}_{n} ) * V ( {t}_{n} ) * Δ t )}^{2} ) + 1} + D ;$$
wherein R0 is the resistance value of the heating element at the preset test temperature, R is the preset resistance value, α, c, d and D are constants, I(tₙ) is the current value recorded for the nth time during the heating element works according to the preset heating rule, V(tₙ) is the voltage value recorded for the nth time during the heating element works according to the preset heating rule, Δt is the duration time, and m is total number of recorded times of the current value during the heating element works according to the preset heating rule.

15. The computer readable storage medium according to claim 11, wherein the step of when ambient temperature is a preset test temperature, detecting a resistance value of a heating element to obtain the resistance value of the heating element at the preset test temperature, further comprising:
obtaining a resistance value of the thermistor which indicates the ambient temperature;
when the resistance value of the thermistor is within a preset range, the ambient temperature is determined as the preset test temperature, detecting a resistance value of a heating element to obtain the resistance value of the heating element at the preset test temperature.

16. A device for obtaining an initial resistance value of a heating element, comprising:
a memory and a processor;
wherein the memory stores therein at least one program instruction;
the processor, by executing the at least one program instruction, implements the method for obtaining an initial resistance value of a heating element according to claim 1.

17. The device according to claim 16, wherein the step of detecting a resistance value of a heating element to obtain the resistance value of the heating element at the preset test temperature, further comprising:
providing the heating element with a preset detection voltage;
detecting current value of the heating element at the preset detection voltage;
determining the resistance value of the heating element at the preset test temperature according to the current value and the preset detection voltage.

18. The device according to claim 16, wherein the step of detecting a resistance value of a heating element to obtain the resistance value of the heating element at the preset test temperature, further comprising:
when a cigarette lighting signal is detected, controlling the heating element to work according to a preset heating rule, which includes a working voltage range of the heating element and/or a working output power range;
before the resistance value of the heating element reaches a preset resistance value, voltage value and current value of the heating element are recorded for many times;
when the resistance value of the heating element reaches the preset resistance value, obtaining a working duration time of the heating element according to the preset heating rule;
determining the resistance value of the heating element at the preset test temperature according the voltage value, current value recorded for many times and working duration time.

19. The device according to claim 16, wherein the step of determining the resistance value of the heating element at the preset test temperature according the voltage value, current value recorded for many times and working duration time, further comprising:
calculating the resistance value of the heating element at the preset test temperature according to a preset formula, which is:
$${R}_{0} = \frac{R}{α ( c {\sum }_{n = 1}^{m} I ( {t}_{n} ) * V ( {t}_{n} ) * Δ t + {d ( {\sum }_{n = 1}^{m} I ( {t}_{n} ) * V ( {t}_{n} ) * Δ t )}^{2} ) + 1} + D ;$$
wherein R0 is the resistance value of the heating element at the preset test temperature, R is the preset resistance value, α, c, d and D are constants, I(tₙ) is the current value recorded for the nth time during the heating element works according to the preset heating rule, V(tₙ) is the voltage value recorded for the nth time during the heating element works according to the preset heating rule, Δt is the duration time, and m is total number of recorded times of the current value during the heating element works according to the preset heating rule.

20. The device according to claim 16, wherein the step of when ambient temperature is a preset test temperature, detecting a resistance value of a heating element to obtain the resistance value of the heating element at the preset test temperature, further comprising:
obtaining a resistance value of the thermistor which indicates the ambient temperature;
when the resistance value of the thermistor is within a preset range, the ambient temperature is determined as the preset test temperature, detecting a resistance value of a heating element to obtain the resistance value of the heating element at the preset test temperature.
